(19) United States
(12) Patent Application Publication
(10) Pub. No.: US 2010/0059757 A1
(43) Pub. Date: Mar. 11, 2010

(54) APPARATUS AND METHOD OF MANUFACTURING THE SAME

(76) Inventors: Myung-Hwan KIM, Yongin-si (KR); Nam-Seok Roh, Seongnam-si (KR); Woo-Jae Lee, Yongin-si (KR); Jung-Hun Noh, Yongin-si (KR)

Correspondence Address: F. CHAU & ASSOCIATES, LLC, 130 WOODBURY ROAD, WOODBURY, NY, 11797, US

(21) Appl. No.: 12/397,556

(22) Filed: Mar. 4, 2009

(30) Foreign Application Priority Data
Sep. 5, 2008 (KR) 10-2008-087885

(51) Int. Cl. B32B 5/02; B05D 3/00; C08J 7/04; B32B 37/12; H01L 33/00

(52) U.S. Cl. 257/72; 427/208.4; 427/516; 428/221; 428/336; 257/E33.053

(57) ABSTRACT

An apparatus includes a substrate having a plurality of pixels, wherein the substrate comprises a concave-convex surface and a cured adhesive layer formed on the concave-convex surface.

### CROSS-REFERENCE TO RELATED APPLICATION

This application claims priority to Korean Patent Application No. 2008-87885 filed on Sep. 5, 2008, the contents of which are herein incorporated by reference in their entirety.

### BACKGROUND OF THE INVENTION

1. Technical Field

The present disclosure relates to an apparatus and a method of manufacturing the same, and more particularly, to an apparatus having a concave-convex substrate and a method of manufacturing the same.

2. Discussion of the Related Art

A flat panel display may be, for example, a liquid crystal display (LCD) or a plasma display panel (PDP). The LCD includes two transparent substrates and a liquid crystal layer interposed between the two substrates. The LCD displays images by adjusting the light transmission in each pixel using rearrangement of the liquid crystal in the liquid crystal layer.

A process for forming the LCD includes a thin film transistor forming process, a color filter forming process, a liquid crystal forming process, and a module forming process. During the process for forming the LCD, a substrate needs to have a low thermal expansion coefficient and a low birefringence. A conventional plastic substrate has high flexibility as compared with a glass or silicon substrate. However, the conventional plastic substrate has a high thermal expansion coefficient and a high birefringence.

When the thermal expansion coefficient of the substrate is higher than a certain value, the substrate is excessively expanded or contracted during the process for forming the LCD. This may result in process defects, such as misalignment or bending of substrates or bending of a substrate carrier. When the birefringence is higher than a certain value, light leakage may occur in the LCD.

### SUMMARY OF THE INVENTION

Exemplary embodiments of the present invention disclose an apparatus including a substrate having a concave-convex surface and including a cured adhesive layer formed on the concave-convex surface to planarize the substrate.

According to an exemplary embodiment of the present invention, an apparatus comprises a substrate having a plurality of pixels, wherein the substrate comprises a concave-convex surface and a cured adhesive layer formed on the concave-convex surface.

The cured adhesive layer may comprise a continuous-phase substance, and a plurality of cross-linked polymers dispersed in the continuous-phase substance.

The cross-linked polymers may comprise cross-linked epoxy resin and a curing agent.

The cross-linked polymers may have a diameter of about 400 nm or less than about 400 nm.

The continuous-phase substance may comprise polymer, epoxy resin and a curing agent.

The polymer may comprise at least one of rubber, polyacryl rubber or silicon rubber.

The cured adhesive layer may have a thickness ranging from about 1.4 μm.

The substrate having the concave-convex surface may comprise at least one of a fiber reinforced plastic substrate, a metal substrate or a sodalime substrate.

The apparatus may further comprise a thin film transistor formed on the cured adhesive layer.

The apparatus may further comprise an impurity blocking layer formed on the cured adhesive layer.

The impurity blocking layer may comprise at least one of a silicon oxide layer or a silicon nitride layer.

The impurity blocking layer may further comprise a transparent acrylate polymer layer.

The apparatus may further comprise a counter substrate facing the substrate and a liquid crystal layer formed between the substrate and the counter substrate.

According to an exemplary embodiment of the present invention, a method of manufacturing an apparatus comprises preparing a substrate having a convex-concave surface, forming an adhesive-pressure sensitive adhesive on the convex-concave surface, and curing the adhesive-pressure sensitive adhesive to form a cured adhesive layer.

The method may further comprise laminating the adhesive-pressure sensitive adhesive on the first substrate before curing the adhesive-pressure sensitive adhesive.

The adhesive-pressure sensitive adhesive may comprise polymer, epoxy resin and a curing agent.

The polymer may comprise at least one of rubber, polyacryl rubber or silicon rubber.

The adhesive-pressure sensitive adhesive can be cured by radiating ultraviolet rays or heat.

A weight of the adhesive-pressure sensitive adhesive can be reduced at a reduction rate of about 0.5% or less than about 0.5%, upon curing the adhesive-pressure sensitive adhesive.

The method may further comprise forming a thin film transistor on the cured adhesive layer.

The method may further comprise forming an impurity blocking layer on the cured adhesive layer.

The blocking layer may comprise at least one of a silicon oxide layer or a silicon nitride layer.

The blocking layer may further comprise a transparent acrylate polymer layer.

The method may further comprise preparing a counter substrate to face the substrate and forming a liquid crystal layer between the substrate and the counter substrate facing the first substrate.

### BRIEF DESCRIPTION OF THE DRAWINGS

Exemplary embodiments of the present disclosure can be understood in more detail from the following description taken in conjunction with the accompanying drawings in which:

FIG. 1 is a plan view showing a part of a liquid crystal display according to an exemplary embodiment of the present invention;

FIG. 2 is a sectional view taken along the line II-II′ of a substrate shown in FIG. 1 according to an exemplary embodiment of the present invention;

FIG. 3 is a view showing a structure of a cured adhesive transformed from an adhesive-pressure sensitive adhesive after a curing reaction;

FIG. 4 is a graph showing transparency of a cured adhesive layer in relation to a wavelength of light passing through the cured adhesive layer according to an exemplary embodiment of the present invention; and

FIGS. 5A to 5H are sectional views showing a method of manufacturing a liquid crystal display according to an exemplary embodiment of the present invention.

### DESCRIPTION OF EXEMPLARY EMBODIMENTS

Exemplary embodiments of the present invention will be described in more detail with reference to the accompanying drawings. The present invention may, however, be embodied in many different forms and should not be construed as limited to the exemplary embodiments set forth herein.

Adhesion according to exemplary embodiments of the present invention refers to a condition in which different bonding surfaces are united by chemical and/or physical forces. The adhesion occurs at an interface between the bonding surfaces. After separating the bonding surfaces from each other, adhesive can remain on the bonding surfaces. The remaining of the adhesive on the bonding surfaces is referred to as cohesive fracture.

Pressure sensitive adhesion according to exemplary embodiments of the present invention refers to a temporary adhesion in which objects can be adhered to each other under light pressure applied for a short period of time. In case of the pressure sensitive adhesion, the adhesive force at the interface is small. Thus, cohesive fracture can be decreased or prevented so that adhesive does not remain on the separated bonding surfaces.

Adhesive-pressure sensitive adhesive according to exemplary embodiments of the present invention refers to material that is a pressure sensitive adhesive when contacting an object. However, cohesive force of the material is increased through a curing process, such as heating or ultraviolet ray radiation, thereby obtaining characteristics of the adhesive in the material.

Cured adhesive according to exemplary embodiments of the present invention refers to a material which serves as adhesive-pressure sensitive adhesive when contacting an object, and serves as adhesive with the lapse of time or through a curing process, such as heating or ultraviolet ray radiation.

Laminate according to exemplary embodiments of the present invention refers to a process of forming a thin film on an object.

Exemplary embodiments of the present invention may be applied to various display apparatuses including an LCD, an organic light emitting display (OLED), a plasma display panel (PDP) or an electrophoretic display.

In a liquid crystal display 100, a plurality of pixels can be formed by a plurality of gate lines 111 and a plurality of data lines 112 crossing the gate lines 111.

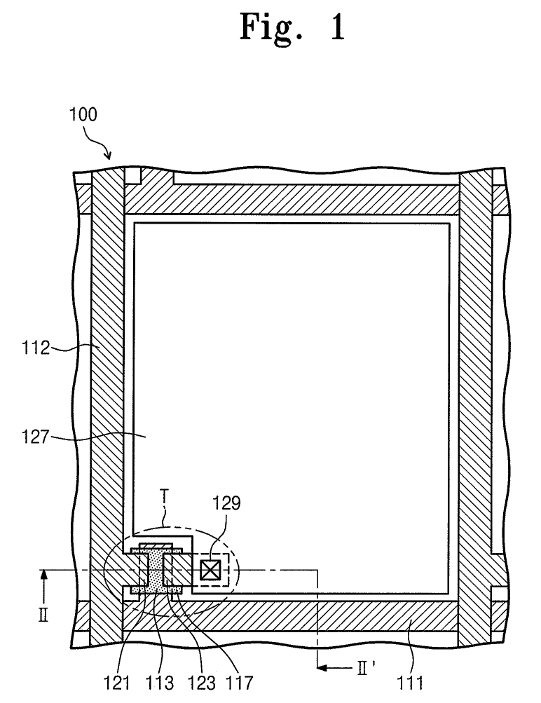

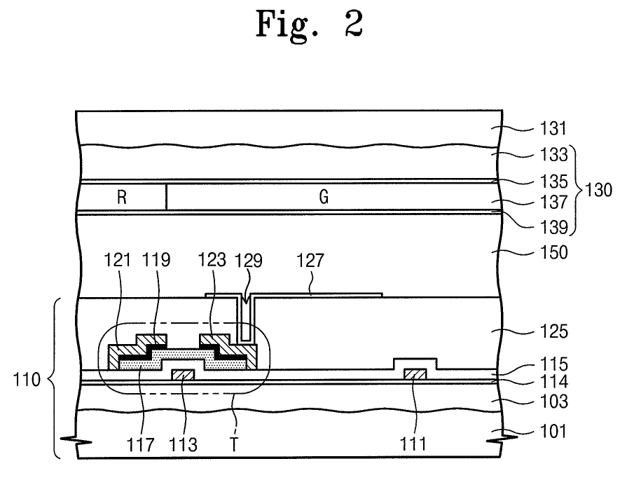

Referring to FIGS. 1 and 2, the liquid crystal display 100 includes a first substrate 110, a second substrate 130 facing the first substrate 110, which is a counter substrate to the first substrate 110, and a liquid crystal layer 150 formed between the two substrates 110 and 130.

The first substrate 110 includes a concave-convex substrate 101. The concave-convex substrate 101 has at least one surface on which a concave-convex section is formed. A cured adhesive layer is formed on the concave-convex substrate 101. According to an exemplary embodiment, a plurality of protrusions and a plurality of depressions are formed on a surface of the concave-convex substrate. That is, the concave-convex substrate 101 includes irregular sections thereon. The concave-convex substrate 101 includes a flexible insulation substrate such as, for example, a fiber reinforced plastic substrate, a metal substrate, and a sodalime substrate. The sodalime substrate includes sodium carbonate (Na₂CO₃).

A cured adhesive layer 103 is formed on the concave-convex substrate 101 comprising fiber reinforced plastic (“fiber reinforced plastic substrate”). The cured adhesive layer 103 can planarize the surface of the fiber reinforced plastic substrate 101. In an exemplary embodiment, the cured adhesive layer 103 is transparent.

A thin film transistor T is formed on the cured adhesive layer 103. A blocking layer 114 is formed on the cured adhesive layer 103 to prevent gas or impurities introduced from the cured adhesive layer 103 or from the outside, from diffusing into the thin film transistor T. In an exemplary embodiment, the blocking layer 114 has a single layer structure including a silicon nitride SiNₓ layer or a silicon oxide SiO₂ layer. In an exemplary embodiment, the blocking layer 114 has a double layer structure including a silicon nitride SiNₓ layer and a transparent acrylate polymer layer, or a silicon oxide layer SiO₂ layer and a transparent acrylate polymer.

The gate lines 111 and the data lines 112 are formed on the blocking layer 114 in a matrix. The thin film transistor T can be formed at intersections of the gate lines 111 and the data lines 112. A pixel electrode 127 can be formed on the pixel area. The pixel electrode 127 is connected to the thin film transistor T to form an electric field in cooperation with a common electrode 139 of the second substrate 130, thereby rearranging liquid crystal molecules of the liquid crystal layer.

The thin film transistor T includes a gate electrode 113 connected to the gate line 111, a source electrode 121 connected to the data line 112 and a drain electrode 123 connected to the pixel electrode 127. The thin film transistor T includes a gate insulating layer 115 to insulate the gate electrode 113 from the source and drain electrodes 121 and 123, an active layer 117, which forms a conduction channel between the source electrode 121 and the drain electrode 123, and an ohmic contact layer 119.

A protective layer 125 is formed on the thin film transistor T, and a contact hole 129 is formed in the protective layer 125 to expose a part of the drain electrode 123 such that the pixel electrode 127 is connected to the drain electrode 123 through the contact hole 129.

The second substrate 130 also includes a concave-convex substrate 131 on which a concave-convex section is formed. A cured adhesive layer 133 is formed on the concave-convex substrate 131.

A color filter 137 is formed on the cured adhesive layer 133 to display colors of the pixel areas. A blocking layer 135 is formed between the cured adhesive layer 133 and the color filter 137 to prevent gas or impurities introduced from the cured adhesive layer 133 or from the outside, from diffusing into the color filter 137. In an exemplary embodiment, the blocking layer 135 may have a single layer structure including a silicon nitride SiNₓ layer or a silicon oxide SiO₂ layer. In an exemplary embodiment, the blocking layer 135 may have a double layer structure, which includes a silicon nitride SiNₓ layer and a transparent acrylate polymer layer or a silicon oxide layer SiO₂ layer and a transparent acrylate polymer layer. The common electrode 139 is formed on the color filter 137 to generate the electric field in cooperation with the pixel electrode 127.

In the liquid crystal display 100, the liquid crystal molecules can be rearranged when a common voltage is applied to the common electrode 139, and a pixel signal output from the data line 112 is provided to the pixel electrode 127 in response to a scan signal received from the gate line 111 in the thin film transistor T. As a result, an electric field is formed between the common electrode 139 and the pixel electrode 127, and the liquid crystal molecules of the liquid crystal layer 150 are tilted by the electric field to change the amount of transmitted light, thereby displaying images.

In an exemplary embodiment, the first substrate 110 and the second substrate 130 include the fiber reinforced plastic substrate. In an exemplary embodiment, the first substrate 110 includes the fiber reinforced plastic substrate and the second substrate 130 includes a different type of substrate such as a glass substrate.

According to an exemplary embodiment, the concave-convex substrates 101, 131 comprise Fiber Reinforced Plastic (FRP) because the FRP has a relatively low thermal expansion coefficient and a relatively low birefringence when compared with those of general plastic. The FRP can be manufactured by impregnating a material such as glass fibers, yarn or cloth comprising glass fibers with organic resin, such as epoxy resin.

When a step difference is formed at a lump portion or overlapping portion of the glass fibers used in the concave-convex substrates 101, 131, a thickness deviation of about 7000 Å to about 8000 Å can occur in a certain area of the substrates.

A step difference formed on a surface of the metal substrate or the low-price sodalime substrate is larger than that formed on an aluminum borosilicate based substrate.

The step difference formed on a substrate may cause display failure or inferior characteristics of the thin film transistor T.

According to an exemplary embodiment of the present invention, the adhesive-pressure sensitive adhesive is laminated on the fiber reinforced plastic substrate 101 to form an adhesive-pressure sensitive adhesive layer. Then the adhesive-pressure sensitive adhesive layer is cured to form the cured adhesive layer, which removes the step difference and planarizes the substrate.

The adhesive-pressure sensitive adhesive has fluidity under room temperature and a predetermined pressure. Accordingly, the adhesive-pressure sensitive adhesive can be formed in a wide plate shape such as, for example, a film shape. Then the adhesive-pressure sensitive adhesive is laminated on the substrate 101 under a predetermined pressure, so that the adhesive-pressure sensitive adhesive is infiltrated and filled between the irregular sections, resulting in adhesion. This lamination process allows an upper part of the adhesive-pressure sensitive adhesive formed in the film shape to have a surface roughness identical to that of a flat protective film, so that the surface of the fiber reinforced plastic substrate can be planarized. As a result, the step difference formed on the surface of the substrate can be reduced to about 50nm or below.

The cured adhesive layer 103 has a thickness enough to compensate for the step difference of the substrate 101, for example, about 1.4 μm or more than about 1.4 μm. However, in the consideration of the step difference of the substrate 101, the thickness of the cured adhesive layer 103 may become greater or lesser according to the step difference. The cured adhesive layer 103 according to an exemplary embodiment of the present invention has a thickness of about 10 μm.

The adhesive-pressure sensitive adhesive has the film shape or plate shape at room temperature. The adhesive-pressure sensitive adhesive is cured under a predetermined condition of the temperature or radiation of ultraviolet rays. In an exemplary embodiment, the cured adhesive can be transparent and have high heat resistance enough to withstand subsequent high temperature processes such as a thin film transistor manufacturing process or a color filter manufacturing process.

According to an exemplary embodiment of the present invention, the adhesive-pressure sensitive adhesive has an epoxy nano domain structure after the curing process. The adhesive-pressure sensitive adhesive includes a continuous-phase liquefied mixture including polymer such as rubber, polyacryl rubber and silicon rubber, epoxy resin and curing agents.

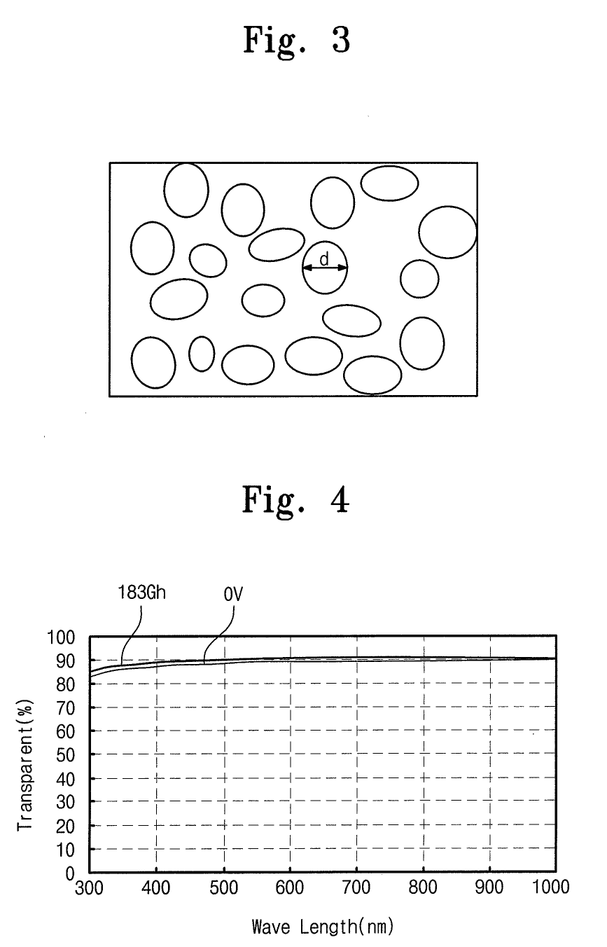

When heat or ultraviolet rays are applied to the adhesive-pressure sensitive adhesive, the epoxy resin reacts with the curing agents to form a cross-linked polymer containing epoxy polymer. FIG. 3 is a view showing a structure of a cured adhesive transformed from an adhesive-pressure sensitive adhesive after a curing reaction.

The curing reaction refers to a process in which the epoxy resin reacts with the curing agents to cause a cross-linking reaction, so that larger polymers are formed. The curing reaction of the epoxy resin and the curing agents is caused by heat or ultraviolet rays applied to the epoxy resin and the curing agents. The cross-linking reaction can be controlled depending on the amount of epoxy resin, the curing agents, and the temperature or the radiation of ultraviolet rays applied to the epoxy resin or the curing agents.

The crosslinked polymers form nano scale lumps, such as, nano domains. That is, when the phase separation in a nano scale occurs, the polymer of adhesive-pressure sensitive adhesive, the epoxy resin and the curing agents, which do not participate in the crosslinking reaction, exist as a continuous phase in a portion where the nano domains are not formed. The nano domains exist as a dispersed phase in the continuous phase mixture including the polymer, the epoxy resin and the curing agents. Accordingly, the adhesive-pressure sensitive adhesive is cured through the above reaction, so that fluidity of the adhesive-pressure sensitive adhesive is decreased. Thus, the adhesive-pressure sensitive adhesive can serve as the cured adhesive.

During the curing reaction, gas or volatile substances contained in the adhesive-pressure sensitive adhesive can be evaporated, so that the weight of the substrate may be reduced. When the weight is substantially reduced, the substrate is contracted or defects are formed on a local area of the substrate. Accordingly, the weight of the adhesive-pressure sensitive adhesive can be reduced at a reduction rate of about 5% or less than about 5% according to an exemplary embodiment of the present invention.

The nano domain may have a diameter d of about 400 nm or less than about 400 nm according to an exemplary embodiment of the present invention. The nano domain can have an average diameter d of about 20 nm in an exemplary embodiment of the present invention. When the nano domain has a diameter of about 400 nm or more than about 400 nm, the scattering degree of light is increased, so that the transparency of the substrate is reduced. The cured adhesive 103 laminated on the fiber reinforced plastic substrate 101 can have transparency of at least about 75% to achieve a predetermined level of brightness. FIG. 4 is a graph showing transparency of a cured adhesive layer in relation to a wavelength of light passing through the cured adhesive layer according to an exemplary embodiment of the present invention. The adhesive-pressure sensitive adhesive is cured to form the cured adhesive layer. The cured adhesive layer has a nano domain having a size of about 20 nm. Referring to FIG. 4, the cured adhesive layer according to an exemplary embodiment of the present invention has transparency of about 90% or more than about 90% within a visible ray wavelength range of about 380 nm to about 770 nm. That is, the adhesive having the above wavelength range can be used on the fiber reinforced plastic substrate according to an exemplary embodiment of the present invention.

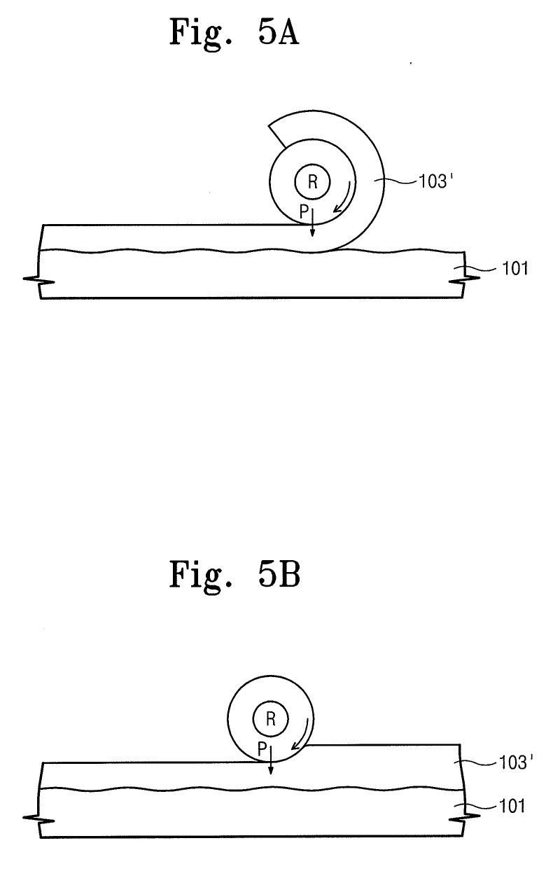

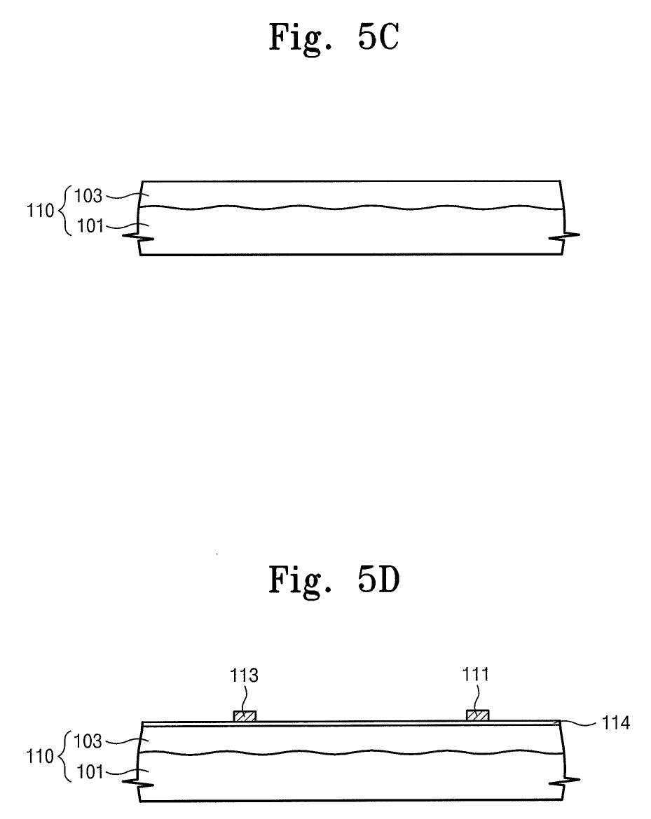

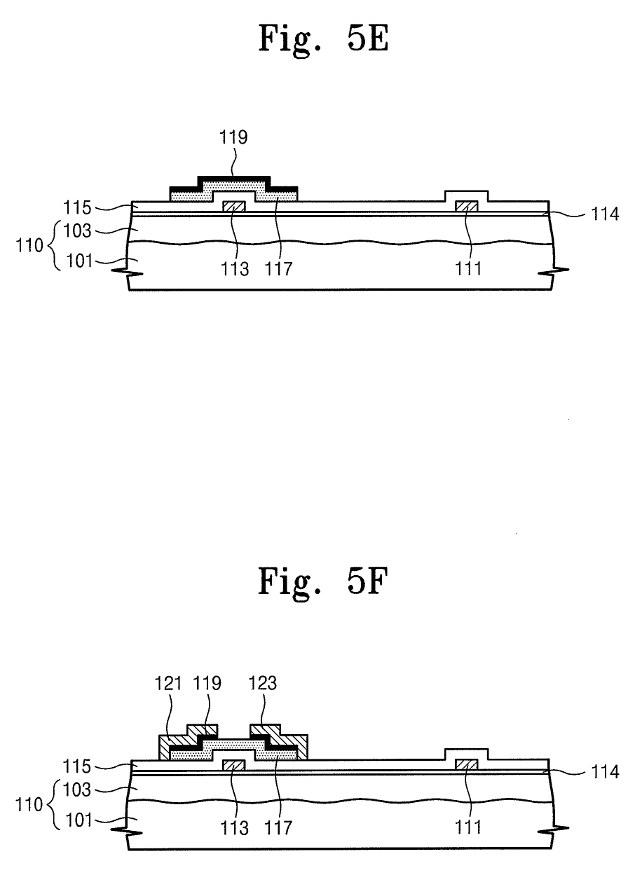

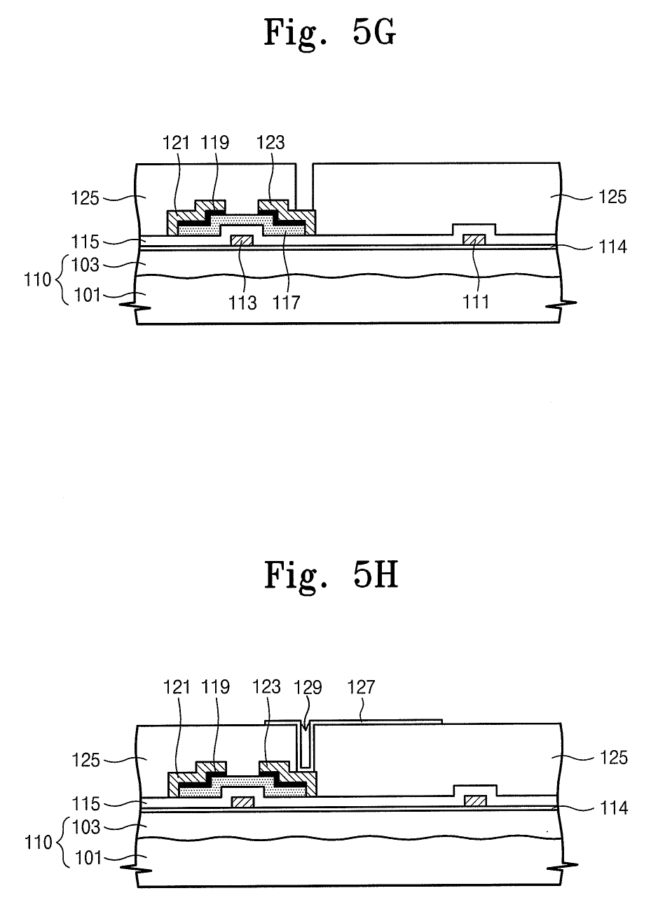

A method of manufacturing a liquid crystal display according to an exemplary embodiment of the present invention is described with reference to FIGS. 5A to 5H. A method of manufacturing a liquid crystal display according to an exemplary embodiment of the present invention includes preparing the first substrate 110 where the cured adhesive layer 103 is formed on the fiber reinforced plastic substrate 101. The second substrate 130 facing the first substrate 110 can be prepared. The liquid crystal layer 150 can be formed between the first substrate 110 and the second substrate 130.

Referring to FIG. 5A or FIG. 5B, the cured adhesive layer 103 is formed on the fiber reinforced plastic substrate 101.

To fabricate the fiber reinforced plastic substrate 101, glass fibers, yarn or cloth can be impregnated with organic resin such as epoxy resin, thereby forming a preliminary substrate. Then, the preliminary substrate is pressed by a press plate having a flat surface and cured with heat. Pressing and curing can be simultaneously performed through a single process.

Then, the cured adhesive layer 103 is formed on the fiber reinforced plastic substrate 101.

The adhesive-pressure sensitive adhesive 103′ is laminated on the fiber reinforced plastic substrate 101. Then the adhesive-pressure sensitive adhesive 103′ is cured with heat, resulting in the cured adhesive layer 103. When the adhesive-pressure sensitive adhesive 103′ is laminated, the adhesive-pressure sensitive adhesive 103′ having a plate shape is wound around a roller R. The roller R is disposed on the surface of the fiber reinforced plastic substrate 101, and the roller R rolls over the fiber reinforced plastic substrate 101 under a predetermined pressure p suitable for lamination. (See FIG. 5A) Alternately, the adhesive-pressure sensitive adhesive 103′ is coated on the entire surface of the fiber reinforced plastic substrate 101. Then, a roller R is disposed on the adhesive-pressure sensitive adhesive 103′, and the roller R rolls over the adhesive-pressure sensitive adhesive 103′ under a predetermined pressure p suitable for lamination. (See FIG. 5B) Then, ultraviolet rays are projected or heat is applied to the adhesive-pressure sensitive adhesive 103′ to cure the adhesive-pressure sensitive adhesive 103′ laminated on the fiber reinforced plastic substrate 101 (See FIG. 5C).

Referring to FIG. 5D, the blocking layer 114 including silicon nitride or silicon oxide is formed on the fiber reinforced plastic substrate 101 on which the cured adhesive layer 103 is formed. The gate electrode 113 and the gate line 111 are formed on the blocking layer 114. In an exemplary embodiment, the gate electrode 113 and the gate line 111 are formed by depositing a first conductive layer on the entire area of the first substrate 110 and then patterning the first conductive layer through such as a photolithography process.

Referring to FIG. 5E, the gate insulating layer 115, the amorphous silicon layer, and n⁺ amorphous silicon layer are sequentially deposited on the entire area of the first substrate 110, on which the gate electrode 113 and the gate line 111 are formed. Then, the photolithography process is performed to selectively pattern the amorphous silicon layer and n⁺ amorphous silicon layer, thereby forming an active layer 117 and an ohmic contact layer 119. The ohmic contact layer 119 allows the active layer 117 to make an ohmic contact with the source electrode 121 and the drain electrode 123.

Referring to FIG. 5F, a second conductive layer is deposited on the entire area of the first substrate 101 on which the active layer 117 and the ohmic contact layer 119 are formed. The second conductive layer is selectively patterned through the photolithography process, thereby forming the source electrode 121 and the drain electrode 123 including the second conductive layer. The source electrode 121 is a part of the data line 112, which substantially crosses the gate line 111.

According to an exemplary embodiment, the active layer 117, the ohmic contact layer 119 and the source and drain electrodes 121 and 123 can be formed through a single photolithography process using, for example, a diffraction mask or half tone mask.

Referring to FIG. 5G, the protective layer 125 is deposited on the entire area of the first substrate 110, on which the source electrode 121 and the drain electrode 123 are formed. The protective layer 125 is partially removed to form the contact hole 129 through which a part of the drain electrode 123 is exposed using, for example, a photolithography.

Referring to FIG. 5H, a transparent conductive material is deposited on the entire area of the first substrate 110 and then patterned through the photolithography process, thereby forming the pixel electrode 127. The pixel electrode 127 is electrically connected to the drain electrode 123 through the contact hole 129.

According to an exemplary embodiment of the present invention, the second substrate 130 can be prepared by laminating the adhesive-pressure sensitive adhesive on the fiber reinforced plastic substrate 131 and then curing the adhesive-pressure sensitive adhesive to form the cured adhesive layer 133. The blocking layer 135 is formed on the cured adhesive layer 133, and then the color filer 137 is formed on the blocking layer 135 through, for example, photolithography. The common electrode 139 including transparent conductive material is formed on the color filter 137.

According to an exemplary embodiment, the first substrate 110 and the second substrate 130 can be disposed opposite to each other, and then the liquid crystal layer is formed between the two substrates 110 and 130.

According to an exemplary embodiment, the concave-convex substrate such as the fiber reinforced plastic substrate is planarized by the cured adhesive layer. As such, the step difference of the substrate is reduced. Accordingly, defects caused by the step difference during subsequent LCD manufacturing processes can be reduced.

Although exemplary embodiments have been described with reference to the accompanying drawings, it is to be understood that the present invention is not limited to these exemplary embodiments but various changes and modifications can be made by one skilled in the art without departing from the spirit and scope of the present invention. All such changes and modifications are intended to be included within the scope of the invention as defined by the appended claims.

What is claimed is:

1. An apparatus comprising:
a substrate having a plurality of pixels,
wherein the substrate comprises a non-flat surface and
a cured adhesive layer disposed on the non-flat surface.

2. The apparatus of claim 1, wherein the non-flat surface comprises a concave-convex surface.

3. The apparatus of claim 1, wherein the cured adhesive layer comprises:
a continuous-phase substance; and
a plurality of cross-linked polymers dispersed in the continuous-phase substance.

4. The apparatus of claim 2, wherein the cross-linked polymers comprise cross-linked epoxy resin and a curing agent.

5. The apparatus of claim 2, wherein the cross-linked polymers have a diameter of about 400 nm or less than about 400 nm.

6. The apparatus of claim 2, wherein the continuous-phase substance comprises polymer, epoxy resin and a curing agent.

7. The apparatus of claim 5, wherein the polymer comprises at least one of rubber, polyacryl rubber or silicon rubber.

8. The apparatus of claim 1, wherein the cured adhesive layer has a thickness ranging from about 1.4 μm.

9. The apparatus of claim 1, wherein the substrate having the concave-convex surface comprises at least one of a fiber reinforced plastic substrate, a metal substrate or a sodalime substrate.

10. The apparatus of claim 1, further comprising a thin film transistor formed on the cured adhesive layer.

11. The apparatus of claim 10, further comprising an impurity blocking layer formed on the cured adhesive layer.

12. The apparatus of claim 11, wherein the impurity blocking layer comprises an acrylate polymer layer.

13. The apparatus of claim 10, wherein the impurity blocking layer comprises at least one of a silicon oxide layer or a silicon nitride layer.

14. The apparatus of claim 13, wherein the impurity blocking layer further comprises a transparent acrylate polymer layer.

15. A method of manufacturing an apparatus, the method comprising:
preparing a substrate having a convex-concave surface;
forming adhesive-pressure sensitive adhesive on the convex-concave surface; and
curing the adhesive-pressure sensitive adhesive to form a cured adhesive layer.

16. The method of claim 15, further comprising
laminating the adhesive-pressure sensitive adhesive on the substrate before curing the adhesive-pressure sensitive adhesive.

17. The method of claim 16, wherein the laminating comprises
disposing a roller on the surface of the substrate, the roller having the adhesive-pressure sensitive adhesive therearound, and
rolling the roller over the substrate under a predetermined pressure.

18. The method of claim 16, wherein the laminating comprises
coating the adhesive-pressure sensitive adhesive on the entire surface of the substrate, and
rolling a roller over the adhesive-pressure sensitive adhesive under a predetermined pressure.

19. The method of claim 16, wherein the adhesive-pressure sensitive adhesive comprises polymer, epoxy resin and a curing agent.

20. The method of claim 19, wherein the polymer comprises at least one of rubber, polyacryl rubber or silicon rubber.

21. The method of claim 16, wherein the adhesive-pressure sensitive adhesive is cured by radiating ultraviolet rays or heat.

22. The method of claim 21, wherein a weight of the adhesive-pressure sensitive adhesive is reduced at a reduction rate of about 0.5% or less than about 0.5%, upon curing the adhesive-pressure sensitive adhesive.
